(19) United States
(12) Patent Application Publication
(10) Pub. No.: US 2026/0293173 A1
(43) Pub. Date: Sep. 24, 2026

(54) SEMICONDUCTOR DEVICE AND METHOD FOR MANUFACTURING

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Takako MOTAI, Yokohama (JP); Yoko IWAKAJI, Tokyo (JP); Kaori FUSE, Nonoichi (JP); Hiroko ITOKAZU, Kawasaki (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/265,667

(22) Filed: Jul. 10, 2025

(30) Foreign Application Priority Data
Mar. 19, 2025 (JP) 2025-045297

(51) Int. Cl. H10D 12/00; H10D 12/01; H10D 62/10; H10D 62/60; H10D 64/00

(52) U.S. Cl. CPC H10D 12/415; H10D 12/038; H10D 12/481; H10D 62/102; H10D 62/60; H10D 64/112

(57) ABSTRACT

A semiconductor device includes a first electrode, a second electrode, and a semiconductor layer. The semiconductor layer includes a first semiconductor region of a first conductivity type, multiple guard ring regions of a second conductivity type, and a high-concentration region of the first conductivity type. The multiple guard ring regions are positioned at an upper surface of the semiconductor layer. The high-concentration region is located between two mutually-adjacent guard ring regions among the multiple guard ring regions. The two mutually-adjacent guard ring regions include an outer guard ring region, and an inner guard ring region positioned between the outer guard ring region and the element region. The high-concentration region is separated from the inner guard ring region. A first-conductivity-type impurity concentration in the high-concentration region is greater than a first-conductivity-type impurity concentration in the first semiconductor region, and is not more than 1.5×10¹⁶/cm³.

### CROSS-REFERENCE TO RELATED APPLICATIONS

This application is based upon and claims the benefit of priority from Japanese Patent Application No. 2025-045297, filed on Mar. 19, 2025; the entire contents of which are incorporated herein by reference.

### FIELD

Embodiments relate to a semiconductor device and a method for manufacturing.

### BACKGROUND

A semiconductor device includes, for example, an element region that includes elements such as IGBTs (Insulated Gate Bipolar Transistors), MOSFETS (Metal-Oxide-Semiconductor field-effect transistors), diodes, and the like, and a termination region outside the element region.

### BRIEF DESCRIPTION OF THE DRAWINGS

FIG. 1 is a schematic plan view illustrating a semiconductor device according to an embodiment;

FIG. 2 is a schematic cross-sectional view illustrating the semiconductor device according to the embodiment;

FIG. 3 is a graph illustrating a simulation of electric fields of semiconductor devices;

FIG. 4 is a graph illustrating a simulation of potential differences of the semiconductor devices;

FIG. 5 is a graph illustrating the first-conductivity-type impurity concentration distribution in the Z-direction of the semiconductor layer;

FIG. 6 is a graph illustrating a simulation of the breakdown voltage;

FIG. 7 is a graph illustrating a simulation of the breakdown voltage;

FIGS. 8A to 8C are schematic cross-sectional views illustrating parts of the semiconductor device according to the embodiment;

FIG. 9 is a graph illustrating the first-conductivity-type impurity concentration distribution in the Z-direction of the semiconductor layer;

FIG. 10 is a schematic cross-sectional view illustrating a part of a semiconductor device according to an embodiment;

FIG. 11 is a graph illustrating a portion of the impurity concentration along line La illustrated in FIG. 10;

FIG. 12 is a schematic cross-sectional view illustrating a part of a semiconductor device according to an embodiment;

FIG. 13 is a graph illustrating a portion of the impurity concentration along line Lb illustrated in FIG. 12;

FIG. 14 is a schematic cross-sectional view illustrating a part of a semiconductor device according to an embodiment;

FIG. 15 is a schematic cross-sectional view illustrating a part of a semiconductor device according to an embodiment;

FIG. 16 is a schematic cross-sectional view illustrating a part of a semiconductor device according to an embodiment;

FIGS. 17A and 17B are schematic cross-sectional views illustrating a method for manufacturing a semiconductor device according to an embodiment;

FIGS. 18A and 18B are schematic cross-sectional views illustrating the method for manufacturing the semiconductor device according to the embodiment;

FIGS. 19A and 19B are schematic cross-sectional views illustrating a method for manufacturing another semiconductor device according to an embodiment;

FIGS. 20A and 20B are schematic cross-sectional views illustrating the method for manufacturing another semiconductor device according to the embodiment; and

FIG. 21 is a schematic cross-sectional view illustrating the method for manufacturing another semiconductor device according to the embodiment.

### DETAILED DESCRIPTION

A semiconductor device according to an embodiment includes a first electrode, a second electrode, and a semiconductor layer. The second electrode is positioned above the first electrode. The semiconductor layer is positioned between the first electrode and the second electrode in a vertical direction. The semiconductor layer includes a first semiconductor region of a first conductivity type, multiple guard ring regions of a second conductivity type, and a high-concentration region of the first conductivity type. The first semiconductor region includes an element region, and a termination region surrounding the element region. The multiple guard ring regions surround the element region in the termination region and are positioned at an upper surface of the semiconductor layer. The high-concentration region is located between two mutually-adjacent guard ring regions among the multiple guard ring regions. The two mutually-adjacent guard ring regions include an outer guard ring region, and an inner guard ring region positioned between the outer guard ring region and the element region. The high-concentration region is separated from the inner guard ring region. A first-conductivity-type impurity concentration in the high-concentration region is greater than a first-conductivity-type impurity concentration in the first semiconductor region, and is not more than 1.5×10¹⁶/cm³.

A semiconductor device according to another embodiment includes a first electrode, a second electrode, and a semiconductor layer. The second electrode is positioned above the first electrode. The semiconductor layer is positioned between the first electrode and the second electrode in a vertical direction. The semiconductor layer includes a first semiconductor region of a first conductivity type, multiple guard ring regions of a second conductivity type, and a high-concentration region of the first conductivity type. The first semiconductor region includes an element region, and a termination region surrounding the element region. The multiple guard ring regions surround the element region in the termination region and are positioned at an upper surface of the semiconductor layer. The high-concentration region is located between two mutually-adjacent guard ring regions among the multiple guard ring regions. The two mutually-adjacent guard ring regions include an outer guard ring region, and an inner guard ring region positioned between the outer guard ring region and the element region. The high-concentration region is separated from the inner guard ring region and the outer guard ring region. A first-conductivity-type impurity concentration in the high-concentration region is greater than a first-conductivity-type impurity concentration in the first semiconductor region.

A method for manufacturing a semiconductor device according to an embodiment includes a process of preparing a semiconductor layer including a first semiconductor region of a first conductivity type and multiple guard ring regions of a second conductivity type. The first semiconductor region is located in an element region, and in a termination region surrounding the element region. The multiple guard ring regions are located on the first semiconductor region in the termination region and surround the element region. The manufacturing method includes a process of forming multiple conductive parts. Portions of the multiple conductive parts are positioned respectively above the multiple guard ring regions; and the multiple conductive parts are electrically connected respectively with the multiple guard ring regions. The manufacturing method includes a process of forming a high-concentration region of the first conductivity type on the first semiconductor region between two mutually-adjacent guard ring regions among the multiple guard ring regions by performing ion implantation using the multiple conductive parts as a mask. A first-conductivity-type impurity concentration in the high-concentration region is greater than a first-conductivity-type impurity concentration in the first semiconductor region. A dose of a first-conductivity-type impurity in the ion implantation is not more than 3.5×10¹²/cm².

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

In the embodiments described below, each embodiment may be implemented by inverting the p-type (an example of the second conductivity type) and the n-type (an example of the first conductivity type) of each semiconductor region.

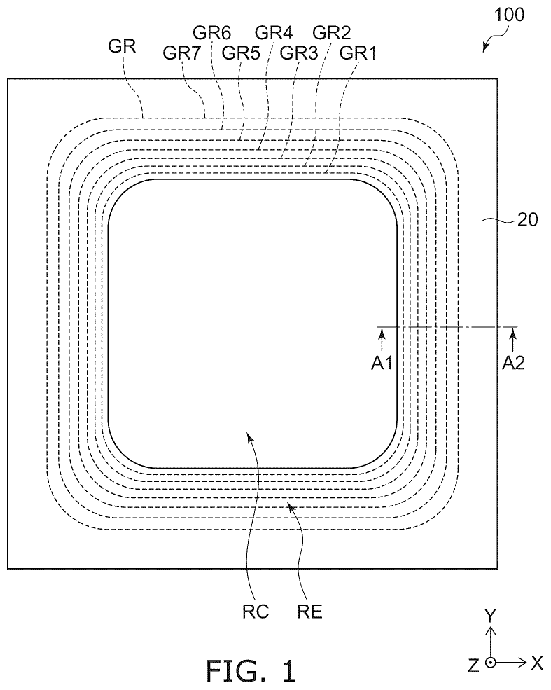

FIG. 1 is a schematic plan view illustrating a semiconductor device according to an embodiment.

As illustrated in FIG. 1, the semiconductor device 100 according to the embodiment includes an element region RC, and a termination region RE surrounding the element region RC. In the example, an IGBT is located in the element region RC. An element such as a MOSFET, a diode, etc., may be located in the element region RC.

The semiconductor device 100 includes a semiconductor layer 20. The semiconductor layer 20 (the semiconductor device 100) has a rectangular shape including sides extending in an X-direction and sides extending in a Y-direction. The semiconductor device 100 also includes a first electrode 11 (e.g., a collector electrode) and a second electrode 12 (e.g., an emitter electrode) positioned above the first electrode 11, which are described below. The semiconductor layer 20 is positioned between the first electrode 11 and the second electrode 12 in the vertical direction (a Z-direction). The semiconductor layer 20 is located in the element region RC and the termination region RE.

The semiconductor layer 20 includes multiple guard ring regions GR. The guard ring regions GR are located in the termination region RE at the front surface of the semiconductor layer 20. The guard ring regions GR have ring shapes surrounding the entire perimeter of the element region RC. The multiple guard ring regions GR are separated from each other. Parts of the semiconductor device 100 such as the second electrode 12, etc., are not illustrated in FIG. 1.

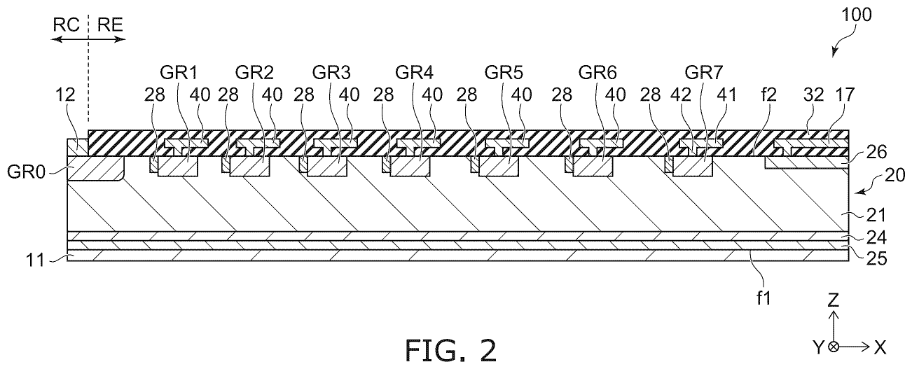

FIG. 2 is a schematic cross-sectional view illustrating the semiconductor device according to the embodiment.

FIG. 2 illustrates a cross section along line A1-A2 shown in FIG. 1, that is, a cross section of the termination region RE and a section of the element region RC.

As illustrated in FIG. 2, the second electrode 12 is separated from the first electrode 11 in the Z-direction. In the description of the embodiment, the direction from the first electrode 11 toward the second electrode 12 is referred to as the Z-direction (a first direction). In the description, the direction from the first electrode 11 toward the second electrode 12 is called “up/above”, and the opposite direction is called “down/below”. These directions are based on the relative positional relationship between the first electrode 11 and the second electrode 12 and are independent of the direction of gravity. The X-direction, the Y-direction, and the Z-direction are perpendicular to each other. For example, the semiconductor layer 20 is a semiconductor substrate; the Z-direction is the thickness direction of the semiconductor substrate; and the X-direction and the Y-direction are parallel to major surfaces (a lower surface f1 and an upper surface f2) of the semiconductor substrate.

The semiconductor layer 20 is positioned between the first electrode 11 and the second electrode 12 in the element region RC. The semiconductor layer 20 includes the lower surface f1 at the first electrode 11 side and the upper surface f2 at the second electrode 12 side. The lower surface f1 and the upper surface f2 extend along the X-Y plane. The first electrode 11 contacts the lower surface f1 and is electrically connected with the semiconductor layer 20. The second electrode 12 contacts the upper surface f2 and is electrically connected with the semiconductor layer 20.

The semiconductor layer 20 includes a first semiconductor region 21 (e.g., a drift region), a fourth semiconductor region 24 (e.g., a buffer region), and a fifth semiconductor region 25 (e.g., a collector region).

The first electrode 11, the fourth semiconductor region 24, the semiconductor region 25, and the first semiconductor region 21 extend across the element region RC and the termination region RE. The second electrode 12 is located in the element region RC.

The fifth semiconductor region 25 is located on the first electrode 11. The fifth semiconductor region 25 contacts the first electrode 11. The fifth semiconductor region 25 is of a second conductivity type.

The fourth semiconductor region 24 is located on the fifth semiconductor region 25. The fourth semiconductor region 24 is of a first conductivity type.

The first semiconductor region 21 is located on the fourth semiconductor region 24. The first semiconductor region 21 is of the first conductivity type. The first-conductivity-type impurity concentration in the first semiconductor region 21 is less than the first-conductivity-type impurity concentration in the fourth semiconductor region 24.

In the example, guard ring regions GR0 to GR7 are included as multiple guard ring regions GR. The guard ring regions GR are located on the first semiconductor region 21 at the upper surface f2 side of the semiconductor layer 20. The guard ring regions GR extend downward from the upper surface f2. The guard ring regions GR are semiconductor regions of the second conductivity type. The second-conductivity-type impurity concentrations in the guard ring regions GR are, for example, not less than 1×10¹⁷/cm³. Parts of the first semiconductor region 21 are positioned between adjacent guard ring regions GR.

The guard ring region GR0, the guard ring region GR1, the guard ring region GR2, the guard ring region GR3, the guard ring region GR4, the guard ring region GR5, the guard ring region GR6, and the guard ring region GR7 are arranged in this order from the element region RC side. For example, the potentials of the guard ring regions GR are in a floating state. For example, the guard ring regions GR suppress electric field concentration by causing a depletion layer to spread in the termination region RE.

As in FIG. 2, a portion of the guard ring region GR0 may extend beyond the boundary between the element region RC and the termination region RE and extend into the end portion of the element region RC.

The guard ring region GR0 extends below the second electrode 12. The second electrode 12 contacts the top of the guard ring region GR0 and is electrically connected with the guard ring region GR0.

For example, the multiple guard ring regions GR1 to GR7 have the same second-conductivity-type impurity concentration. The second-conductivity-type impurity concentration in the guard ring region GR0 may be greater than the second-conductivity-type impurity concentrations in the other guard ring regions GR1 to GR7.

The semiconductor layer 20 also includes multiple high-concentration regions 28 in the termination region RE. The high-concentration regions 28 are semiconductor regions of the first conductivity type. The first-conductivity-type impurity concentrations in the high-concentration regions 28 are greater than the first-conductivity-type impurity concentration in the first semiconductor region 21.

Each high-concentration region 28 is positioned between two mutually-adjacent guard ring regions GR among the multiple guard ring regions GR. In other words, one high-concentration region 28 is positioned between two guard ring regions GR. The guard ring regions GR and the high-concentration regions 28 are alternately arranged in the X-direction.

The high-concentration regions 28 extend along the guard ring regions GR in the X-Y plane. In other words, similarly to the guard ring regions GR, the high-concentration regions 28 may have ring shapes surrounding the element region RC.

For example, the high-concentration region 28 that is between the guard ring region GR2 and the guard ring region GR3 is separated from the guard ring region GR2. That is, a part of the first semiconductor region 21 is positioned between the high-concentration region 28 and the guard ring region GR2 and contacts the high-concentration region 28 and the guard ring region GR2. Thus, the high-concentration region 28 between two mutually-adjacent guard ring regions GR is separated from the inner guard ring region GR among the two guard ring regions GR.

Among two mutually-adjacent guard ring regions GR, the guard ring region GR that is relatively proximate to the element region RC is called an inner guard ring region GR; and the guard ring region GR that is relatively distant to the element region RC is called an outer guard ring region. In other words, the inner guard ring region GR is positioned between the element region RC and the outer guard ring region GR.

In the example of FIG. 2, the high-concentration region 28 between the two mutually-adjacent guard ring regions GR contacts the outer guard ring region GR among the two guard ring regions GR. In other words, for example, the high-concentration region 28 between the guard ring region GR2 and the guard ring region GR3 contacts the guard ring region GR3 and forms a p-n junction with the guard ring region GR3.

In the termination region RE, multiple electrodes 40 are located on the semiconductor layer 20. The electrodes 40 are located respectively on the guard ring regions GR1 to GR7 and are electrically connected respectively with the guard ring regions GR1 to GR7. More specifically, each electrode 40 includes a contact part 42 contacting the upper surface of the guard ring region GR, and a conductive part 41 that is wider than the contact part 42. The contact part 42 and the conductive part 41 extend along the guard ring region GR in the X-Y plane. In other words, similarly to the guard ring region GR, the electrode 40 may have a ring shape surrounding the element region RC. The electrode 40 is, for example, a field plate. For example, the potential of the electrode 40 is floating. It is desirable for the electrode 40 and the high-concentration region 28 not to overlap in the Z-direction.

The semiconductor layer 20 includes a semiconductor region 26 positioned in the outer end portion of the termination region RE. The semiconductor region 26 is located on the first semiconductor region 21 and surrounds the element region RC. The semiconductor region 26 is, for example, an EQPR (Equi-potential Ring). The first-conductivity-type impurity concentration in the semiconductor region 26 is greater than the first-conductivity-type impurity concentration in the first semiconductor region 21. An electrode 17 is located on the semiconductor region 26 in contact with the semiconductor region 26, and is electrically connected with the semiconductor region 26.

An insulating layer 32 is located on the semiconductor layer 20 (the guard ring regions GR, the first semiconductor region 21, and the semiconductor region 26), the electrode 40, and the electrode 17 in the termination region RE. Parts of the electrodes 40 and the electrode 17 are separated from the first semiconductor region 21 by the insulating layer 32.

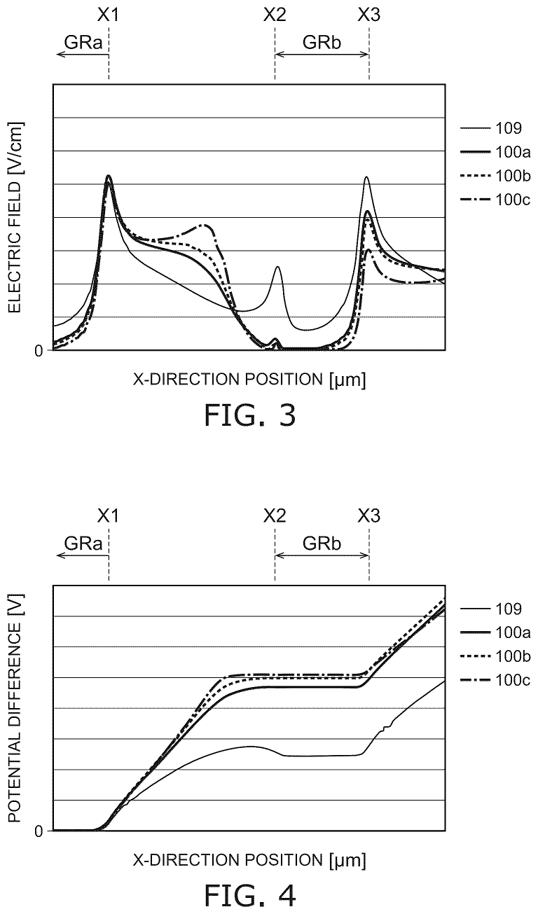

FIG. 3 is a graph illustrating a simulation of electric fields of semiconductor devices.

A positive voltage with respect to the second electrode 12 is applied to the first electrode 11. FIG. 3 illustrates electric field intensities of semiconductor devices 109a, 100a, 100b, and 100c. FIG. 3 illustrates the electric field intensity along the X-direction at the depth of the lower end vicinity of the guard ring region GR. FIG. 3 illustrates the electric field intensity around two mutually-adjacent guard ring regions GR (an inner guard ring region GRa and an outer guard ring region GRb). A position X1 illustrated in FIG. 3 corresponds to the end of the inner guard ring region GRa. Positions X2 and X3 correspond to ends of the outer guard ring region GRb.

A semiconductor device 109 differed from the semiconductor device 100 according to the embodiment above in that the high-concentration region 28 was not included. Similarly to the semiconductor device 100, the semiconductor devices 100a, 100b, and 100c included the high-concentration region 28. The first-conductivity-type impurity concentration in the high-concentration region 28 increased in the order of the semiconductor devices 100a, 100b, and 100c.

As shown in FIG. 3, the electric field intensity became high between the position X1 and the position X2 when the high-concentration region 28 was included. In other words, the electric field intensity became high between the two guard ring regions GR.

FIG. 4 is a graph illustrating a simulation of potential differences of the semiconductor devices.

FIG. 4 illustrates potential differences of the semiconductor devices 109, 100a, 100b, and 100c. FIG. 4 illustrates potential differences in a range similar to FIG. 3. The potential difference of FIG. 4 is the absolute value of the potential difference with respect to the potential of the inner guard ring region GRa in the semiconductor devices.

As shown in FIG. 4, the potential change between the position X1 and the position X2 (i.e., between the two guard ring regions GR) became large when the high-concentration region 28 was included. By including the high-concentration region 28, the potential change in the termination region RE can be increased. For example, the potential is reduced more away from the element region RC.

Thus, by including the high-concentration region 28, the electric field intensity between the guard ring regions GR can be increased, and efficient electric field control in the termination region RE is possible. The electric field distribution in the termination region RE can be improved. As a result, for example, the termination region RE can be reduced, and the semiconductor device can be smaller.

Each guard ring region GR has an inner end (at the element region RC side) and an outer end (at the side opposite to the element region RC). The inner end is between the outer end and the element region RC. The electric field tends to be strong at the outer end of each guard ring region GR. For example, as illustrated in FIG. 3, the electric field intensity has peaks at the positions X1 and X3 (i.e., corners of the guard ring regions GR). In the semiconductor device 100 as described above, the high-concentration region 28 is separated from the inner guard ring region GR among the two mutually-adjacent guard ring regions GR. In other words, the high-concentration regions 28 are separated from the outer ends (e.g., the position X1) of the guard ring regions GR. For example, the electric field intensity at the position X1 is not greatly increased by including the high-concentration region 28. Thus, for example, an increase of the electric field at the outer end of the guard ring region GR can be suppressed. For example, the potential difference between the guard ring regions GR can be increased while suppressing the electric field at the corners of the guard ring regions GR. For example, the semiconductor device can be made smaller while suppressing the reduction of the breakdown voltage.

As described above with reference to FIG. 2, the high-concentration region 28 may contact the outer guard ring region GR. In such a case, the distance between the high-concentration region 28 and the inner guard ring region GR can be increased. As a result, for example, the electric field at the corner of the inner guard ring region GR is easily suppressed further.

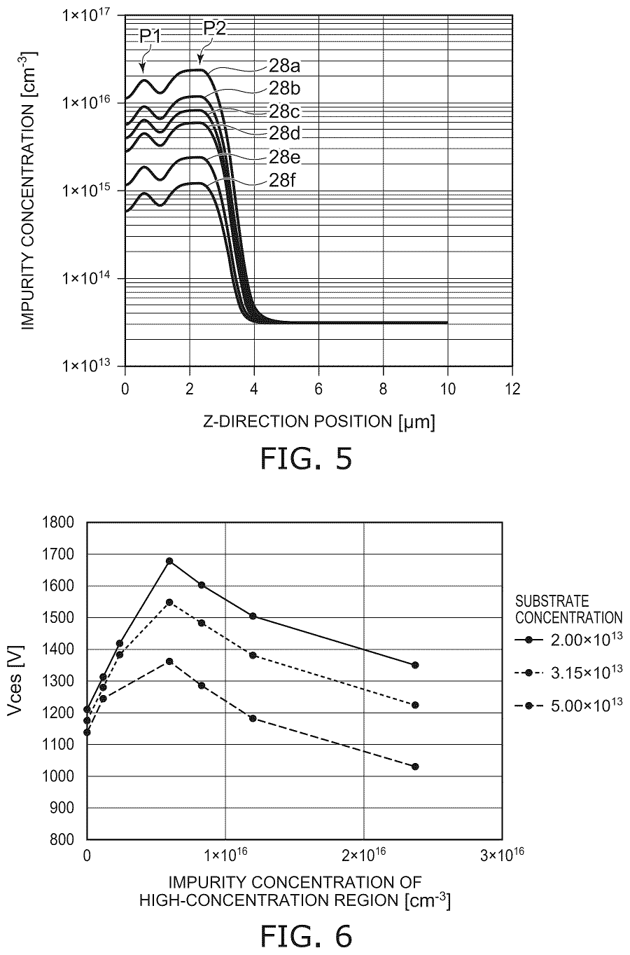

FIG. 5 is a graph illustrating the first-conductivity-type impurity concentration distribution in the Z-direction of the semiconductor layer.

The horizontal axis is the Z-direction distance (the depth) from the upper surface f2 of the semiconductor layer 20. FIG. 5 illustrates the impurity concentration distribution from the upper end of the high-concentration region 28 to the first semiconductor region 21.

FIG. 5 illustrates impurity concentration distributions when high-concentration regions 28a to 28f were formed as the high-concentration region 28. The high-concentration regions 28a to 28f had mutually-different doses.

In the example, the first-conductivity-type impurity concentration in the Z-direction of each high-concentration region 28 has a peak P1 and a peak P2. The shallow peak P1 and the deep peak P2 have, for example, about equal values. The value of the deep peak P2 may be, for example, greater than the value of the shallow peak P1. FIG. 6 is a graph illustrating a simulation of the breakdown voltage.

The vertical axis is a breakdown voltage Vces between the collector and the emitter of the semiconductor device. The horizontal axis is the first-conductivity-type impurity concentration in the high-concentration region 28. The horizontal axis corresponds to the peak concentration of the first-conductivity-type impurity in the high-concentration region 28. The values along the horizontal axis are plots of the impurity concentrations at the peak P2 vicinity of the high-concentration regions 28a to 28f shown in FIG. 5. Specifically, the impurity concentrations at a depth of 2 μm of the high-concentration regions 28a to 28f shown in FIG. 5 are plotted. When the high-concentration region 28 was not included, the impurity concentration of the first semiconductor region 21 was about 10¹³/cm³, and so the plots are as close to zero as possible on the horizontal axis.

FIG. 6 illustrates cases where the substrate concentration (i.e., the first-conductivity-type impurity concentration in the first semiconductor region 21) was 2×10¹³/cm³, 3.15×10¹³/cm³, and 5×10¹³/cm³. According to the embodiment, the first-conductivity-type impurity concentration in the first semiconductor region 21 is, for example, not less than 1×10¹³/cm³ and not more than 7×10¹³/cm³.

For each substrate concentration as shown in FIG. 6, the breakdown voltage increased as the horizontal axis value increased within the range of not less than 1×10¹⁵/cm³ and not more than 6×10¹⁵/cm³. The breakdown voltage had peaks when the horizontal axis value was about 6×10¹⁵/cm³. Then, the breakdown voltage decreased as the horizontal axis value increased. In the semiconductor device 109 in which the high-concentration region 28 was not formed, the electric field intensity between the guard ring regions GR was low, and the breakdown voltage was low; however, the breakdown voltage was increased by forming the high-concentration region 28. When the concentration of the high-concentration region 28 became too high, the electric field intensity between the guard ring regions GR increased, and the breakdown voltage decreased. When the electric field intensity between the guard ring regions GR is high and the breakdown voltage has a pronounced reduction, there is a possibility that the breakover immunity may decrease, etc., and so it is desirable for the concentration of the high-concentration region 28 to be a concentration around where the breakdown voltage has a peak.

For each of the substrate concentrations of 2×10¹³/cm³, 3.15×10¹³/cm³, and 5×10¹³/cm³, the breakdown voltage when the horizontal axis value was not more than 1.5×10¹⁶/cm³ was greater than the breakdown voltage when the high-concentration region 28 was not included (when the horizontal axis value was near zero). When the substrate concentration was 5×10¹³/cm³, the breakdown voltage when the horizontal axis value was near zero was about equal to the breakdown voltage when the horizontal axis value was 1.5×10¹⁶/cm³.

According to the embodiment, the first-conductivity-type impurity concentration in the high-concentration region 28 is, for example, not more than 1.5×10¹⁶/cm³. In such a case, the breakdown voltage can be higher than when the high-concentration region 28 is not included. For example, the first-conductivity-type impurity concentration in the high-concentration region 28 is not more than 1.0×10¹⁶/cm³.

For example, the first-conductivity-type impurity concentration in the high-concentration region 28 is not less than 2.5×10¹⁵/cm³ and not more than 1.0×10¹⁶/cm³. In such a case, the ratio of the breakdown voltage decrease to the breakdown voltage peak is, for example, not more than about 10%.

For example, the first-conductivity-type impurity concentration in the high-concentration region 28 is not less than 4.0×10¹⁵/cm³ and not more than 9.0×10¹⁵/cm³. In such a case, the ratio of the breakdown voltage decrease to the breakdown voltage peak is, for example, not more than about 7.5%.

For example, the first-conductivity-type impurity concentration in the high-concentration region 28 is not less than 5.0×10¹⁵/cm³ and not more than 8.0×10¹⁵/cm³. In such a case, the ratio of the breakdown voltage decrease to the breakdown voltage peak is, for example, not more than about 5%.

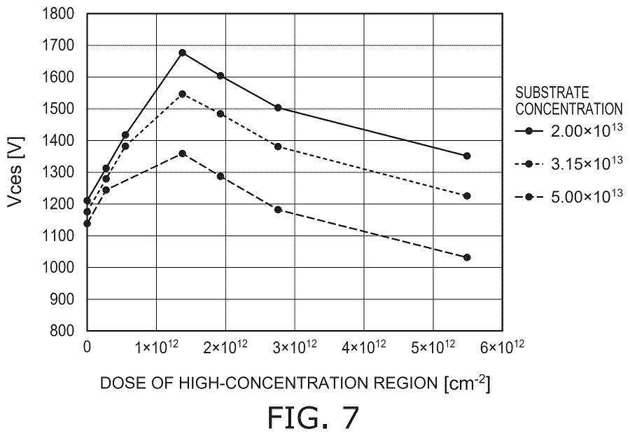

FIG. 7 is a graph illustrating a simulation of the breakdown voltage.

Similarly to FIG. 6, the vertical axis is the breakdown voltage Vces between the collector and the emitter. The horizontal axis is the first conductivity type dose of the high-concentration region 28. In other words, the horizontal axis is the first-conductivity-type impurity count per unit area of the high-concentration region 28. Assuming the activation rate is about 100%, the horizontal axis corresponds to the value of the impurity concentration shown in FIG. 5 integrated over the depth in the range of the substrate concentration and higher. Or, assuming the activation rate is about 100%, the horizontal axis corresponds to the impurity amount of the high-concentration region 28 per unit area of the XY-plane. In FIG. 7, the first conductivity type doses of the high-concentration regions 28a to 28f shown in FIG. 5 are plotted. When the high-concentration region 28 was not included, the impurity concentration of the first semiconductor region 21 was about 10¹³/cm³, and is plotted as close to zero as possible on the horizontal axis. FIG. 7 also illustrates substrate concentrations of 2×10¹³/cm³, 3.15×10¹³/cm³, and 5×10¹³/cm³.

According to the embodiment, the dose of the first-conductivity-type impurity in the high-concentration region 28 is, for example, not more than 3.5×10¹²/cm². In such a case, the breakdown voltage can be higher than when the high-concentration region 28 is not included. For example, the dose of the first-conductivity-type impurity in the high-concentration region 28 is not more than 2.4×10¹²/cm².

For example, the dose of the first-conductivity-type impurity in the high-concentration region 28 is not less than 8.0×10¹¹/cm² and not more than 2.4×10¹²/cm². In such a case, the ratio of the breakdown voltage decrease to the breakdown voltage peak is, for example, not more than about 10%.

For example, the dose of the first-conductivity-type impurity in the high-concentration region 28 is not less than 9.0×10¹¹/cm² and not more than 2.2×10¹²/cm². In such a case, the ratio of the breakdown voltage decrease to the breakdown voltage peak is, for example, not more than about 7.5%.

For example, the dose of the first-conductivity-type impurity in the high-concentration region 28 is not less than 1.0×10¹²/cm² and not more than 2.0×10¹²/cm². In such a case, the ratio of the breakdown voltage decrease to the breakdown voltage peak is, for example, not more than about 5%.

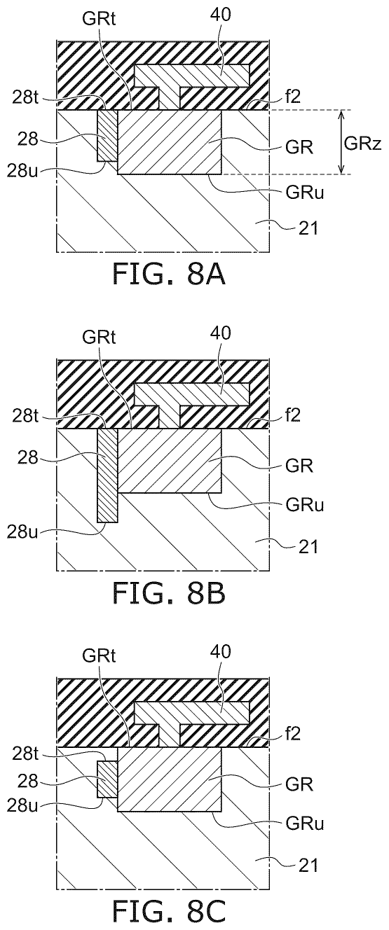

FIGS. 8A to 8C are schematic cross-sectional views illustrating parts of the semiconductor device according to the embodiment. These drawings are enlarged illustrations of the periphery of the high-concentration region 28 in a cross section similar to FIG. 2.

In the example of FIG. 8A, an upper end 28t of the high-concentration region 28 and an upper end GRt of the guard ring region GR are positioned at the upper surface f2 of the semiconductor layer 20. A portion of the upper surface f2 is formed of the high-concentration region 28 and the guard ring region GR. A lower end 28u of the high-concentration region 28 is higher than a lower end GRu of the guard ring region GR. For example, a length GRz in the Z-direction of the guard ring region GR is not less than 3 μm and not more than 10 μm.

As in the example of FIG. 8B, the lower end 28u of the high-concentration region 28 may be lower than the lower end GRu of the guard ring region GR. In such a case, for example, the electric field intensity is increased even at a deeper position.

As in the example of FIG. 8C, the upper end 28t of the high-concentration region 28 may be lower than the upper surface f2 of the semiconductor layer 20. In such a case, for example, the electric field at the front side is suppressed, and breakdown voltage degradation due to an external charge is suppressed. The semiconductor region that is on the high-concentration region 28 has a lower first-conductivity-type impurity concentration than the high-concentration region 28. For example, a part of the first semiconductor region 21 may be positioned on the high-concentration region 28.

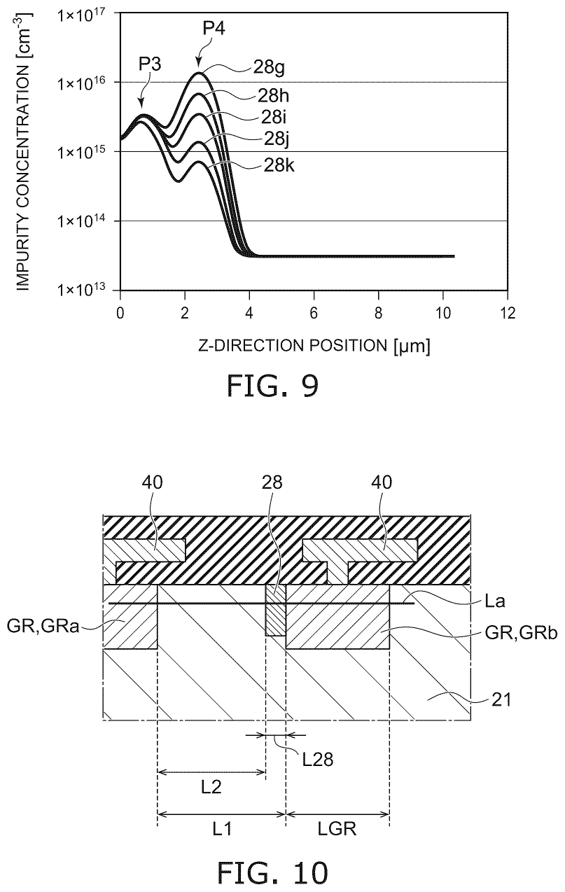

FIG. 9 is a graph illustrating the first-conductivity-type impurity concentration distribution in the Z-direction of the semiconductor layer.

The horizontal axis and the vertical axis are similar to those of FIG. 5. FIG. 9 illustrates the impurity concentration distributions when high-concentration regions 28g to 28k were formed as the high-concentration region 28. The high-concentration regions 28g to 28k had mutually-different doses.

In the example, the first-conductivity-type impurity concentration in the Z-direction of each high-concentration region 28 had a peak P3 and a peak P4. The value of the deep peak P4 may be greater or less than the value of the shallow peak P3.

As described with reference to FIGS. 5 and 9, the first-conductivity-type impurity concentration distribution in the Z-direction (the depth direction) of the high-concentration region 28 may have multiple peaks. The high-concentration region 28 can be formed by introducing an impurity into the substrate by ion implantation and by annealing. For example, multiple peaks can be formed by performing ion implantation multiple times with different acceleration voltages.

For example, a method may be considered in which a deep high-concentration region 28 is formed by annealing at a high temperature after ion implantation. When, however, the annealing temperature is too high, there is also a possibility that discrepancies such as crystal defects of the semiconductor, etc., may occur. In contrast, by performing ion implantation multiple times with different acceleration voltages, for example, a deep high-concentration region 28 can be obtained while suppressing the annealing temperature.

For example, in view of breakdown voltage, it is sufficient for the higher peak concentration among the peaks P3 and P4 to be not more than the upper limit of the desirable concentration range described above (e.g., not more than 1.5×10¹⁶/cm³). For example, in the case of the high-concentration region 28k, the breakdown voltage can be maintained by setting the peak P3 having the maximum value to be not more than the upper limit of the desirable concentration range.

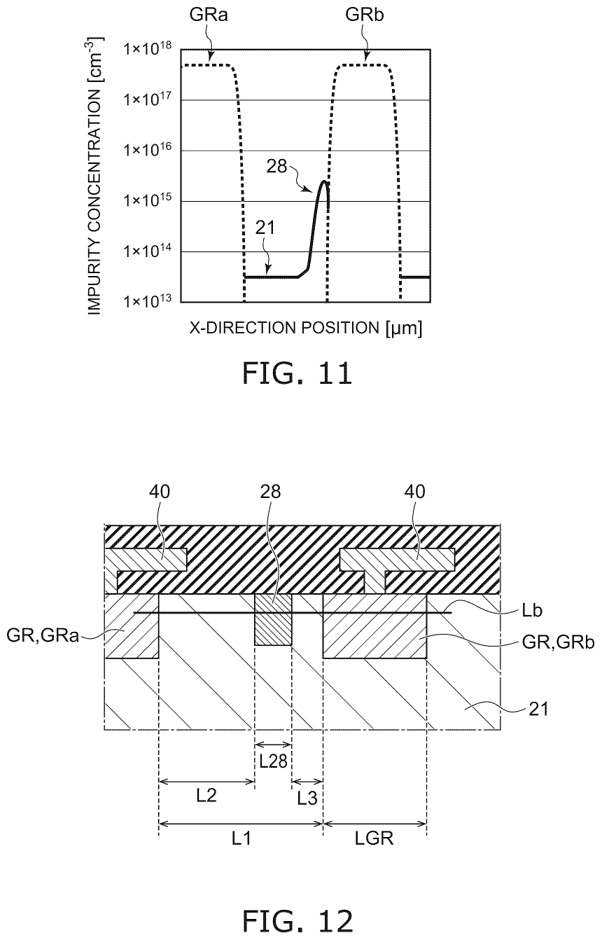

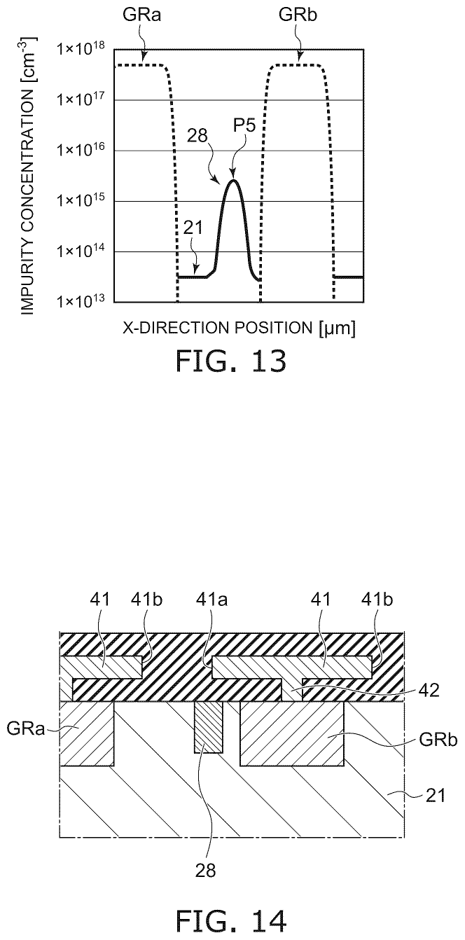

FIG. 10 is a schematic cross-sectional view illustrating a part of a semiconductor device according to an embodiment. FIG. 11 is a graph illustrating a portion of the impurity concentration along line La illustrated in FIG. 10. In FIG. 11 (and FIG. 13 below), the first-conductivity-type impurity concentration is illustrated by solid lines; and the second-conductivity-type impurity concentration is illustrated by broken lines. The first-conductivity-type impurity concentration in the first semiconductor region 21 may be constant in FIG. 11.

As illustrated in FIG. 10, the width of the high-concentration region 28, i.e., a length L28 in the X-direction, may be less than half of a length L1 between the two mutually-adjacent guard ring regions GR. The length L28 of the high-concentration region 28 may be less than a length L2 between the inner guard ring region GRa and the high-concentration region 28. The length L28 of the high-concentration region 28 may be less than the width of the outer guard ring region GRb, i.e., a length LGR in the X-direction. For example, a strong electric field at the end of the inner guard ring region GRa can be suppressed by ensuring the distance between the high-concentration region 28 and the inner guard ring region GRa.

FIG. 12 is a schematic cross-sectional view illustrating a part of a semiconductor device according to an embodiment. FIG. 13 is a graph illustrating a portion of the impurity concentration along line Lb illustrated in FIG. 12.

As illustrated in FIG. 12, the high-concentration region 28 may be separated from the outer guard ring region GRb. In such a case, the area between the guard ring regions GR in which the electric field is strong may be increased by the high-concentration region 28. As a result, for example, the change of the potential between the guard ring regions GR can be increased.

In the example of FIG. 12, a length L3 between the high-concentration region 28 and the outer guard ring region GRb is less than the length L28 of the high-concentration region 28 and less than the length L2. When the length L3 is set to be less than the length L2, the region in which the potential difference is generated as shown in FIG. 4 can be wider between the inner guard ring region GRa and the high-concentration region 28, and so the electric field distribution can be improved, and the termination region RE can be reduced. Thus, by locating the high-concentration region 28 proximate to the outer guard ring region GRb, for example, an increase of the electric field at the corner of the inner guard ring region GRa can be suppressed.

As in FIG. 13, the position of a peak P5 of the first-conductivity-type impurity concentration may be separated from the outer guard ring region GRb along the X-direction. In other words, a semiconductor region that has a lower first-conductivity-type impurity concentration than the high-concentration region 28 may be positioned between the outer guard ring region GRb and the high-concentration region 28. A part of the first semiconductor region 21 may be positioned between the guard ring region GRb and the high-concentration region 28.

When the high-concentration region 28 is separated from the outer guard ring region GRb, the effects of the impurity included in the high-concentration region 28 on the conductivity type of the guard ring region GRb can be reduced. For example, the high-concentration region 28 is of the n-conductivity type; and the guard ring region GRb is of the p-conductivity type. The effects on the p-conductivity type of the guard ring region GRb due to the n-type impurity included in the high-concentration region 28 diffusing into the guard ring region GRb are reduced. For example, a reduction of the effective acceptor concentration of the guard ring region GRb due to donors included in the high-concentration region 28 can be suppressed.

The width (the length LGR) of the guard ring region GR is, for example, not less than 9 μm and not more than 16 μm. The width (the length L28) of the high-concentration region 28 is, for example, not less than 2 μm and not more than 6 μm. The spacing (the length L1) of the guard ring region GR is, for example, not less than 10 μm and not more than 30 μm.

FIG. 14 is a schematic cross-sectional view illustrating a part of a semiconductor device according to an embodiment.

At least a portion of the guard ring region GR is between the first semiconductor region 21 and at least a portion of the conductive part 41. In the example of FIG. 14, the conductive part 41 is positioned above the entire guard ring region GR. In other words, the entire guard ring region GR overlaps the conductive part 41 in the Z-direction.

The conductive part 41 includes an inner end 41a at the element region RC side, and an outer end 41b at the side opposite to the inner end 41a. The inner end 41a is between the outer end 41b and the element region RC.

For example, in the Z-direction, the high-concentration region 28 does not overlap the outer end 41b of the conductive part 41 electrically connected with the inner guard ring region GRa. The high-concentration region 28 is separated further from the element region RC than the outer end 41b of the conductive part 41 electrically connected with the inner guard ring region GRa. For example, effects of the high-concentration region 28 on the electric field at the corner of the inner guard ring region GRa can be suppressed.

In the example, in the Z-direction, the high-concentration region 28 overlaps the inner end 41a of the conductive part 41 electrically connected with the outer guard ring region GRb. However, as in FIG. 10 above, etc., the inner end 41a may be positioned directly above the guard ring region GR, and may not overlap the high-concentration region 28 in the Z-direction. Also, the conductive part 41 may extend further toward the element region RC side than the example of FIG. 14 so that the conductive part 41 is positioned above the entire high-concentration region 28.

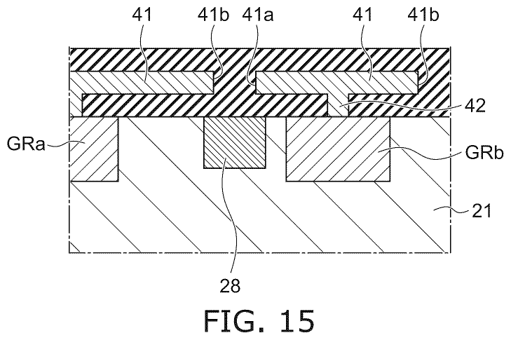

FIG. 15 is a schematic cross-sectional view illustrating a part of a semiconductor device according to an embodiment.

Thus, the high-concentration region 28 may overlap, in the Z-direction, at least one of the conductive part 41 electrically connected with the inner guard ring region GRa or the conductive part 41 electrically connected with the outer guard ring region GRb. In the example of FIG. 15, the high-concentration region 28 overlaps the inner end 41a and the outer end 41b in the Z-direction. As described below, the high-concentration region 28 can be formed by ion implantation using the conductive part 41 as a mask.

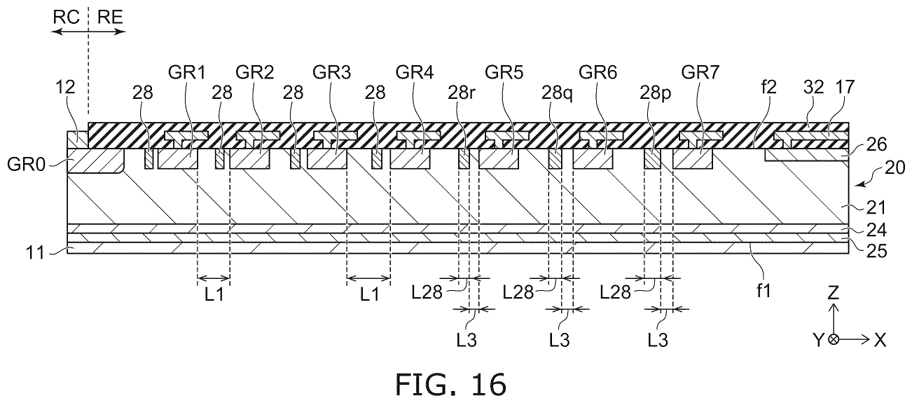

FIG. 16 is a schematic cross-sectional view illustrating a part of a semiconductor device according to an embodiment.

The multiple high-concentration regions 28 include an outer high-concentration region 28p, an inner high-concentration region 28q, and an inner high-concentration region 28r. The high-concentration region 28q is positioned between the element region RC and the high-concentration region 28p. The high-concentration region 28r is positioned between the high-concentration region 28q and the element region RC.

In the example, the widths of the multiple high-concentration regions 28 increase away from the element region RC. In other words, for example, the width (the length L28) of the high-concentration region 28p is greater than the width (the length L28) of the high-concentration region 28q. The width of the high-concentration region 28q is greater than the width (the length L28) of the high-concentration region 28r. Thus, the width of the high-concentration region 28 may be increased away from the element region RC. By widening the high-concentration region 28, for example, the change of the potential can be increased.

In the example, the distance (the length L3) between the high-concentration region 28 and the guard ring region GR increases away from the element region RC. In other words, for example, the spacing between the high-concentration region 28p and the guard ring region GR7 may be greater than the spacing between the high-concentration region 28q and the guard ring region GR6. For example, the spacing between the high-concentration region 28q and the guard ring region GR6 may be greater than the spacing between the high-concentration region 28r and the guard ring region GR5. Thus, the spacing between the high-concentration region 28 and the guard ring region GR most proximate to the high-concentration region 28 increases away from the element region RC. Also, the distance (the length L1) between the guard ring regions GR increases away from the element region RC.

For example, the change of the potential can be increased by increasing the spacing between the guard ring regions GR at positions distant to the element region RC.

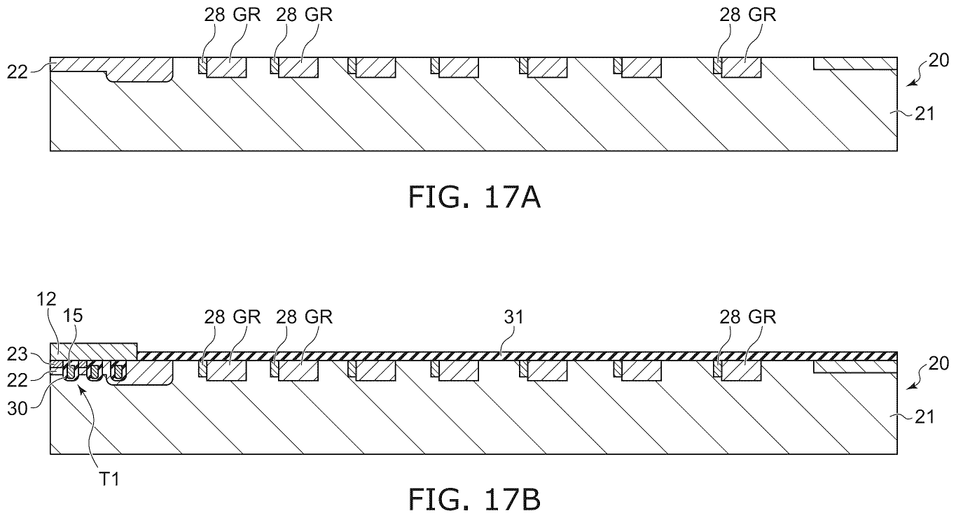

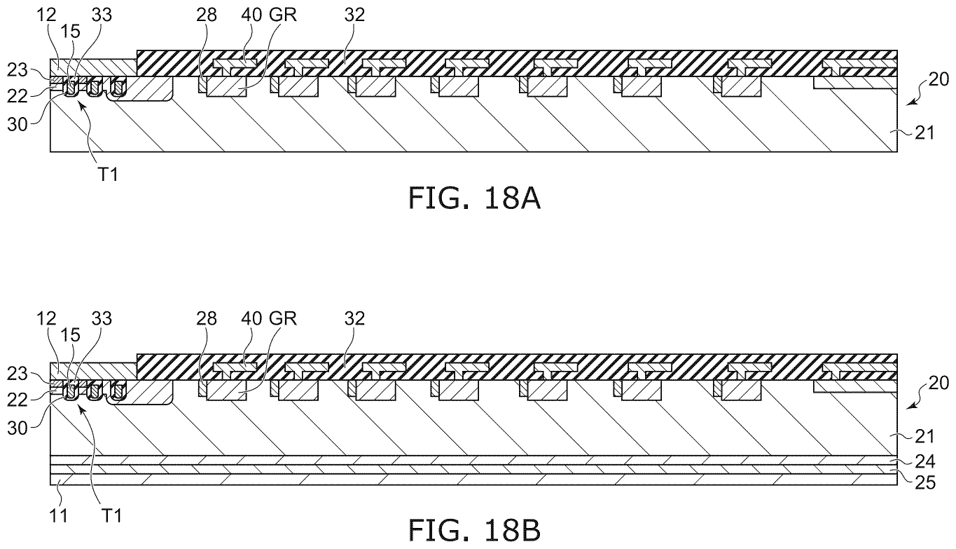

FIGS. 17A, 17B, 18A, and 18B are schematic cross-sectional views illustrating a method for manufacturing a semiconductor device according to an embodiment.

As illustrated in FIG. 17A, the guard ring regions GR and the high-concentration regions 28 of the termination region RE are formed by ion implantation into a semiconductor substrate (the semiconductor layer 20 that includes the first semiconductor region 21). For example, regions other than the regions into which ions will be implanted are covered with a resist, and diffusion layers that are used to form the guard ring regions GR and the high-concentration regions 28 are sequentially formed in the termination region RE. The guard ring region GR of the termination region RE is formed by ion-implanting boron (B⁺). The high-concentration region 28 is formed by ion-implanting phosphorus (P⁺). Continuing, the diffusion layers of the element region RC are formed. Specifically, a second semiconductor region 22 (e.g., a base region) is formed by ion implantation. The desired shape can be formed while suppressing diffusion by activating after ion implantation by performing low-temperature heat treatment at not more than 1,000° C.

Then, as illustrated in FIG. 17B, trenches T1, conductive parts 15 (e.g., gate electrodes), insulating layers 30, a third semiconductor region 23 (e.g., a source region), and the second electrode 12 are formed in the element region RC. The termination region RE is covered with an insulating layer 31.

As illustrated in FIG. 18A, the electrode 40 that is connected with the guard ring region GR is formed. The termination region RE is covered with the insulating layer 32. Subsequently, the backside of the semiconductor layer 20 is polished and thinned to have a prescribed thickness.

Subsequently, as illustrated in FIG. 18B, the fourth semiconductor region 24 is formed by ion-implanting P into the entire back surface of the semiconductor layer 20. The fifth semiconductor region 25 is formed by ion-implanting B into the back surface of the semiconductor layer 20. Activation is performed by low-temperature annealing such as laser annealing, etc. The first electrode 11 is formed on the back surface of the semiconductor layer 20.

Although the electrode 40 is one layer in the example, multiple layers of field plates may be used. The fifth semiconductor region 25 that is formed at the back surface of the semiconductor layer 20 may not necessarily be formed in the termination region RE.

The semiconductor device 100 can be formed as described above.

The second semiconductor region 22 is located on the first semiconductor region 21 in the element region RC. In other words, the second semiconductor region 22 is between the first semiconductor region 21 and the second electrode 12. The second semiconductor region 22 is of the second conductivity type. The third semiconductor region 23 is located on a portion of the second semiconductor region 22 in the element region RC. In other words, the third semiconductor region 23 is between the second semiconductor region 22 and the second electrode 12. The third semiconductor region 23 is of the first conductivity type.

The conductive part 15 faces the first semiconductor region 21, the second semiconductor region 22, and the third semiconductor region 23 via the insulating layer 30. In the example, the conductive part 15 and the insulating layer 30 are located inside the trench T1 in the semiconductor layer 20. The trench T1 extends in the Z-direction from the upper surface f2 of the substrate to the first semiconductor region 21. The insulating layer 30 is located at the inner wall of the trench T1. The insulating layer 30 contacts the first semiconductor region 21, the second semiconductor region 22, and the third semiconductor region 23. The conductive part 15 is located at the inner side of the insulating layer 30 inside the trench T1 and is insulated from the semiconductor layer 20 by the insulating layer 30. The conductive part 15 is arranged in the X-direction with the first semiconductor region 21, the second semiconductor region 22, and the third semiconductor region 23.

The second electrode 12 contacts the second semiconductor region 22 and the third semiconductor region 23 and is electrically connected with the second semiconductor region 22 and the third semiconductor region 23. The second electrode 12 is insulated from the conductive part 15 by an insulating layer 33.

Examples of the materials of the components of the semiconductor device 100 will now be described.

The semiconductor layer 20 (the semiconductor regions included in the semiconductor layer 20) include silicon, silicon carbide, gallium nitride, or gallium arsenide as a semiconductor material. For example, the semiconductor layer 20 is a semiconductor substrate such as a silicon substrate, etc.

When silicon is used as the semiconductor material, arsenic, phosphorus, or antimony can be used as an n-type impurity. Boron can be used as a p-type impurity.

The conductive part 15 includes a conductive material such as polysilicon, etc. An impurity may be added to the conductive material.

The insulating layers 30, 31, 32, and 33 include insulating materials such as silicon oxide, silicon nitride, etc.

The first electrode 11, the second electrode 12, the electrode 40, and the electrode 17 are conductive parts that include metals such as aluminum, copper, etc.

Operations of the semiconductor device 100 will now be described.

A voltage that is not less than a threshold is applied to the conductive part 15 in a state in which a positive voltage with respect to the second electrode 12 is applied to the first electrode 11. As a result, an inversion layer is formed in the second semiconductor region 22; and the state is set to an on-state. For example, electrons flow from the second electrode 12 toward the first semiconductor region 21 via the third semiconductor region 23 and the inversion layer. For example, holes flow from the first electrode 11 toward the first semiconductor region 21 via the fourth semiconductor region 24. Subsequently, when the voltage applied to the conductive part 15 drops below the threshold, the inversion layer in the second semiconductor region 22 disappears, and the state is switched to an off-state.

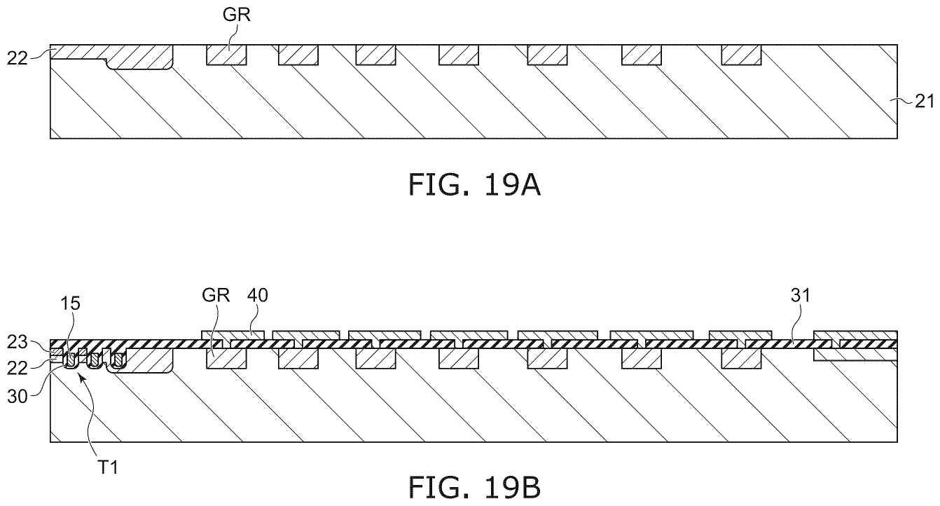

FIGS. 19A, 19B, 20A, 20B, and 21 are schematic cross-sectional views illustrating a method for manufacturing another semiconductor device according to an embodiment.

As illustrated in FIG. 19A, the guard ring regions GR of the termination region RE are formed by ion implantation into a semiconductor substrate. For example, regions other than the regions into which ions will be implanted are covered with a resist; and diffusion layers used to form the guard ring regions GR are formed in the termination region RE. The guard ring region GR of the termination region RE is formed by ion-implanting boron (B⁺). Continuing, diffusion layers of the element region RC are formed. For example, the second semiconductor region 22 is formed by ion implantation. The desired shape can be formed while suppressing diffusion by activating after ion implantation by performing low-temperature heat treatment at not more than 1,000° C.

For example, as illustrated in FIG. 19B, the trenches T1 are formed in the element region RC; and the third semiconductor region 23 and channel stopper layers are formed by ion implantation. Subsequently, the insulating film used to form the insulating layers 30 and 31 is formed; and a poly-Si electrode used to form the conductive parts 15 and the electrodes 40 are formed. The conductive parts 15 and the electrodes 40 are formed by etching the poly-Si electrode. In the example, each electrode 40 covers the entire guard ring region GR that is directly under the electrode 40 and electrically connected with the electrode 40.

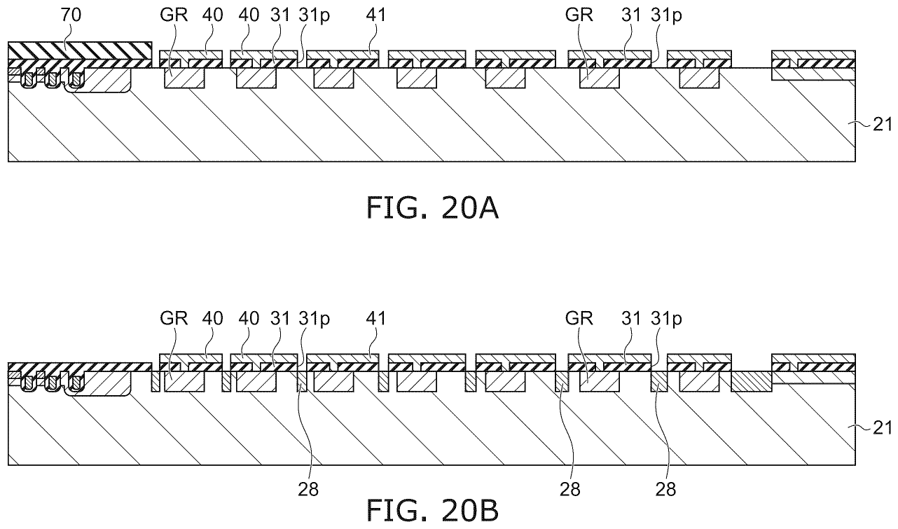

Subsequently, as illustrated in FIG. 20A, the element region RC is protected with a resist 70; and openings 31p are formed in the insulating layer 31 of the termination region RE by etching using the electrodes 40 as a mask. For example, the upper surface of the semiconductor layer 20 is exposed in the openings 31p. A portion of the insulating layer 31 remains between the electrodes 40 and the semiconductor layer 20. As a result, for example, the scattering of ion species outside the semiconductor layer 20 when annealing can be suppressed.

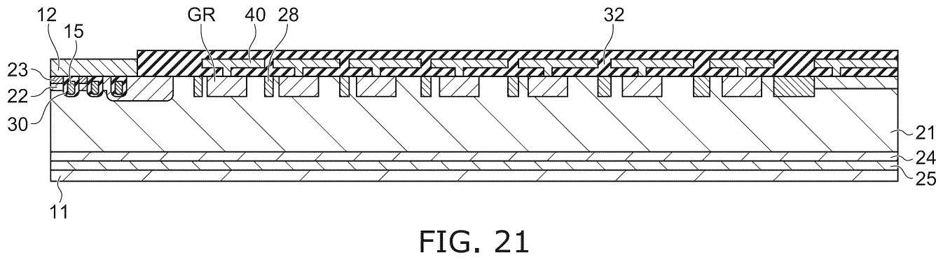

Ion implantation is performed using the electrodes 40 and the insulating layer 31 as a mask; and annealing is performed. As a result, as illustrated in FIG. 20B, the high-concentration regions 28 are formed at the positions of the openings 31p. Subsequently, the termination region RE is covered with the insulating layer 32 as necessary. The second electrode 12, the fourth semiconductor region 24, the fifth semiconductor region 25, and the first electrode 11 are formed similarly to the description described above (see FIG. 21).

In the example, field plate electrodes are formed of the electrodes 40 (the poly-Si electrodes) located on the insulating layer 31 covering the Si front surface in the termination region RE. The field plate electrodes may include multiple layers of electrodes arranged above the electrodes 40 (the poly-Si electrodes).

In the example, the high-concentration region 28 is separated from the guard ring regions GR. Therefore, for example, the electric field can be effectively increased over the entire high-concentration region 28. As a result, even shorter termination in the termination region RE is possible.

As described above, the method for manufacturing the semiconductor device according to the embodiment includes a process of preparing the semiconductor layer 20 that includes the first semiconductor region 21 and the guard ring regions GR (FIG. 19A), a process of forming the conductive parts 15, the insulating layer 30, the second semiconductor region 22, and the third semiconductor region 23 in the element region RC (FIG. 19B), a process of forming the insulating layer 31 on the first semiconductor region 21 (FIG. 19B), and a process of forming the multiple electrodes 40 (the conductive parts 41) (FIG. 19B). The conductive parts 41 are formed on the insulating layer 31.

The manufacturing method according to the embodiment also includes a process of removing at least a portion of the insulating layer 31 (FIG. 20A). For example, as described with reference to FIG. 20A, this process removes a portion of the insulating layer 31 not overlapping the conductive parts while causing a portion of the insulating layer 31 overlapping the conductive parts 41 to remain.

The manufacturing method according to the embodiment includes a process of forming the high-concentration region after the process of removing at least a portion of the insulating layer. This process forms the high-concentration region 28 on the first semiconductor region 21 between two mutually-adjacent guard ring regions GR by ion implantation using the electrodes 40 (the conductive parts 41) as a mask.

According to embodiments, a semiconductor device can be provided in which the electric field distribution in the termination region can be improved.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

In this specification, being “electrically connected” includes not only the case of being connected in direct contact, but also the case of being connected via another conductive member, etc. A state in which one region is in contact with another region does not necessarily mean that the boundary between the regions is clearly observed, and may mean that the regions are continuous with each other or directly connected (joined) to each other.

In each of the embodiments described above, the relative levels of the impurity concentrations between the semiconductor regions can be confirmed using, for example, a SCM (scanning capacitance microscope). The carrier concentration in each semiconductor region can be considered to be equal to the activated impurity concentration in each semiconductor region. Accordingly, the relative levels of the carrier concentrations between the semiconductor regions also can be confirmed using SCM. The relative levels of the impurity concentrations between the semiconductor regions can be considered to correspond to the relative levels of the carrier concentrations between the semiconductor regions. The impurity concentration in each semiconductor region can be measured by, for example, SIMS (secondary ion mass spectrometry).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A semiconductor device, comprising:
a first electrode;
a second electrode positioned above the first electrode;
a semiconductor layer positioned between the first electrode and the second electrode in a vertical direction, the semiconductor layer including
an element region,
a termination region surrounding the element region,
a first semiconductor region located in the element region and the termination region, the first semiconductor region being of a first conductivity type,
a plurality of guard ring regions located in the termination region at an upper surface of the semiconductor layer, the plurality of guard ring regions surrounding the element region, the plurality of guard ring regions being of a second conductivity type, and
a high-concentration region located between two mutually-adjacent guard ring regions among the plurality of guard ring regions, the high-concentration region being of the first conductivity type, the two mutually-adjacent guard ring regions including an outer guard ring region and an inner guard ring region, the inner guard ring region being positioned between the outer guard ring region and the element region, the high-concentration region being separated from the inner guard ring region, a first-conductivity-type impurity concentration in the high-concentration region being greater than a first-conductivity-type impurity concentration in the first semiconductor region, the first-conductivity-type impurity concentration in the high-concentration region being not more than 1.5×10¹⁶/cm³.

2. The device according to claim 1, wherein
the high-concentration region contacts the outer guard ring region.

3. The device according to claim 1, wherein
the high-concentration region is separated from the outer guard ring region.

4. The device according to claim 3, wherein
a distance between the high-concentration region and the outer guard ring region is less than a distance between the high-concentration region and the inner guard ring region.

5. The device according to claim 1, wherein
the first-conductivity-type impurity concentration in the high-concentration region is not less than 2.5×10¹⁵/cm³.

6. The device according to claim 1, further comprising:
a plurality of conductive parts electrically connected respectively with the plurality of guard ring regions,
at least portions of the plurality of guard ring regions being respectively between the first semiconductor region and at least portions of the plurality of conductive parts,
each of the plurality of conductive parts including an outer end, and an inner end positioned between the outer end and the element region,
the high-concentration region being more distant to the element region than the outer end of the conductive part electrically connected with the inner guard ring region.

7. The device according to claim 1, wherein
a plurality of the high-concentration regions is included,
the plurality of high-concentration regions include an outer high-concentration region, and an inner high-concentration region positioned between the outer high-concentration region and the element region, and
a width of the outer high-concentration region is greater than a width of the inner high-concentration region.

8. A semiconductor device, comprising:
a first electrode;
a second electrode positioned above the first electrode;
a semiconductor layer positioned between the first electrode and the second electrode in a vertical direction, the semiconductor layer including
an element region,
a termination region surrounding the element region,
a first semiconductor region located in the element region and the termination region, the first semiconductor region being of a first conductivity type,
a plurality of guard ring regions located in the termination region at an upper surface of the semiconductor layer, the plurality of guard ring regions surrounding the element region, the plurality of guard ring regions being of a second conductivity type, and
a high-concentration region located between two mutually-adjacent guard ring regions among the plurality of guard ring regions, the high-concentration region being of the first conductivity type, the two mutually-adjacent guard ring regions including an outer guard ring region and an inner guard ring region, the inner guard ring region being positioned between the outer guard ring region and the element region, the high-concentration region being separated from the inner guard ring region and the outer guard ring region, a first-conductivity-type impurity concentration in the high-concentration region being greater than a first-conductivity-type impurity concentration in the first semiconductor region.

9. The device according to claim 1, wherein
an upper end of the high-concentration region is positioned at the upper surface of the semiconductor layer.

10. The device according to claim 1, wherein
an upper end of the high-concentration region is lower than the upper surface of the semiconductor layer.

11. The device according to claim 1, wherein
a lower end of the high-concentration region is lower than lower ends of the plurality of guard ring regions.

12. The device according to claim 1, wherein
a lower end of the high-concentration region is higher than lower ends of the plurality of guard ring regions.

13. The device according to claim 1, wherein
the first-conductivity-type impurity concentration in the first semiconductor region is not less than 1×10¹³/cm³ and not more than 7×10¹³/cm³.

14. The device according to claim 1, wherein
a width of the high-concentration region is less than half of a distance between the two mutually-adjacent guard ring regions.

15. The device according to claim 3, wherein
a distance between the high-concentration region and the outer guard ring region is less than a width of the high-concentration region.

16. The device according to claim 1, further comprising:
a plurality of conductive parts electrically connected respectively with the plurality of guard ring regions,
at least portions of the plurality of guard ring regions being respectively between the first semiconductor region and at least portions of the plurality of conductive parts,
the high-concentration region overlapping, in the vertical direction, at least one of the conductive part electrically connected with the inner guard ring region or the conductive part electrically connected with the outer guard ring region.

17. The device according to claim 1, wherein
a first impurity concentration distribution along a depth direction of the high-concentration region has a plurality of peaks.

18. A method for manufacturing a semiconductor device, the method comprising:
preparing a semiconductor layer including
an element region,
a termination region surrounding the element region,
a first semiconductor region located in the element region and the termination region, the first semiconductor region being of a first conductivity type, and
a plurality of guard ring regions located on the first semiconductor region in the termination region, the plurality of guard ring regions surrounding the element region, the plurality of guard ring regions being of a second conductivity type;
forming a plurality of conductive parts so that portions of the plurality of conductive parts are positioned respectively above the plurality of guard ring regions, and so that the plurality of conductive parts are electrically connected respectively with the plurality of guard ring regions; and
forming a high-concentration region on the first semiconductor region between two mutually-adjacent guard ring regions among the plurality of guard ring regions by performing ion implantation using the plurality of conductive parts as a mask, the high-concentration region being of the first conductivity type, a first-conductivity-type impurity concentration in the high-concentration region being greater than a first-conductivity-type impurity concentration in the first semiconductor region, a first-conductivity-type impurity dose in the ion implantation being not more than 3.5×10¹²/cm².

19. The method according to claim 18, further comprising:
forming an insulating layer on the first semiconductor region; and
removing at least a portion of the insulating layer,
the forming of the plurality of conductive parts including forming the plurality of conductive parts on the insulating layer,
the removing of the at least a portion of the insulating layer including causing a portion of the insulating layer overlapping the plurality of conductive parts to remain, and removing a portion of the insulating layer not overlapping the plurality of conductive parts,
the forming of the high-concentration region being performed after the removing of the at least a portion of the insulating layer.
